(19) United States
(12) Patent Application Publication
(10) Pub. No.: US 2025/0285964 A1
(43) Pub. Date: Sep. 11, 2025

(54) DEEP VIA STRUCTURES FOR STACKED TRANSISTOR DEVICES

(71) Applicant: International Business Machines Corporation, Armonk, NY (US)

(72) Inventors: Ruilong Xie, Niskayuna, NY (US); Brent A. Anderson, Jericho, VT (US); Nicholas Anthony Lanzillo, Wynantskill, NY (US); Albert M. Chu, Nashua, NH (US); David Wolpert, Poughkeepsie, NY (US); Lawrence A. Clevenger, Saratoga Springs, NY (US)

(21) Appl. No.: 18/596,803

(22) Filed: Mar. 6, 2024

(51) Int. Cl. H01L 23/528; H01L 27/092; H01L 29/417

(52) U.S. Cl. CPC H01L 23/528; H10D 64/254; H10D 84/85

(57) ABSTRACT

A semiconductor device comprises a plurality of first transistors, a plurality of second transistors stacked on the plurality of first transistors, a plurality of gate isolation regions disposed through respective gate structures of the plurality of second transistors, and a plurality of gate contacts disposed through the plurality of gate isolation regions. The plurality of gate contacts contact respective gate structures of the plurality of first transistors. Respective ones of the plurality of gate isolation regions are located at respective cell boundaries of the plurality of second transistors.

### BACKGROUND

The present application relates to semiconductors, and more specifically, to techniques for forming semiconductor structures. Semiconductors and integrated circuit chips have become ubiquitous within many products, particularly as they continue to decrease in cost and size. There is a continued desire to reduce the size of structural features and/or to provide a greater amount of structural features for a given chip size. Miniaturization, in general, allows for increased performance at lower power levels and lower costs. Present technology is at or approaching atomic level scaling of certain micro-devices such as logic gates, field-effect transistors (FETs), and capacitors.

### SUMMARY

Embodiments of the invention provide structures for and techniques for forming deep vias for stacked transistor devices.

In one embodiment, a semiconductor device includes a plurality of first transistors, a plurality of second transistors stacked on the plurality of first transistors, a plurality of gate isolation regions disposed through respective gate structures of the plurality of second transistors, and a plurality of gate contacts disposed through the plurality of gate isolation regions. The plurality of gate contacts contact respective gate structures of the plurality of first transistors. Respective ones of the plurality of gate isolation regions are located at respective cell boundaries of the plurality of second transistors.

As may be combined with the preceding paragraph, the plurality of gate contacts may contact the respective gate structures of the plurality of first transistors at respective regions between n-type and p-type transistors. The respective cell boundaries of the plurality of second transistors may be offset with respect to respective cell boundaries of the plurality of first transistors. One or more of the plurality of second transistors may include a forksheet transistor.

As may be combined with the preceding paragraphs, the semiconductor device may include a first interconnect wiring level on a first side of a stacked structure including the plurality of second transistors stacked on the plurality of first transistors, and a second interconnect wiring level on a second side of the stacked structure opposite the first side. Wires of the first interconnect wiring level can be spaced apart from each other at a first pitch, and wires of the second interconnect wiring level are spaced apart from each other a second pitch greater than the first pitch. The first side of the stacked structure may be on a frontside of the semiconductor device, and the second side of the stacked structure may be on a backside of the semiconductor device. At least one contact may be disposed from the first side of the stacked structure to the second side of the stacked structure, wherein the at least one contact connects a wire of the first interconnect wiring level with a wire of the second interconnect wiring level.

As may be combined with the preceding paragraphs, a source/drain region of at least one of the first transistors can be connected to a wire of the second interconnect wiring level, wherein the wire of the second interconnect wiring level is misaligned with the source/drain region. The source/drain region may be connected to the wire through a contact having a first portion overlapping the source/drain region and a second portion overlapping the wire.

As may be combined with the preceding paragraphs, the plurality of first transistors and the plurality of second transistors may include a plurality of nanosheet transistors respectively including a plurality of stacked channel regions. The plurality of gate isolation regions may respectively include at least one dielectric layer, and respective ones of the plurality of stacked channel regions in one or more of the plurality of second transistors may contact the at least one dielectric layer.

As may be combined with the preceding paragraphs, the plurality of gate isolation regions may respectively include at least one dielectric layer disposed between a gate contact of the plurality of gate contacts and a gate structure of a second transistor of the plurality of second transistors. A plurality of additional gate isolation regions may be disposed through respective gate structures of the plurality of first transistors, wherein the plurality of additional gate isolation regions are offset from the plurality of gate isolation regions.

Advantageously, illustrative embodiments provide structures for and methods of forming deep vias for stacked transistor devices to connect frontside interconnect wiring levels with backside interconnect wiring levels. For example, wires of a frontside interconnect wiring level can have a smaller pitch and, therefore, more wires than a backside interconnect wiring level. A stacked device architecture (e.g., stacked complementary metal-oxide-semiconductor (CMOS) architecture) uses deep vias (also referred to herein as deep contacts) to connect wires of a frontside interconnect wiring level with wires of a backside interconnect wiring level so that input signals (e.g., gate input signals) can be transmitted from the frontside interconnect wiring level to lower level devices of the stacked device architecture.

In another embodiment, a semiconductor device includes a first transistor structure, a second transistor structure stacked on the first transistor structure, and a gate contact disposed through a gate structure of the second transistor structure. The gate contact contacts a gate structure of the first transistor structure, and is isolated from the gate structure of the second transistor structure by a dielectric layer disposed on sides of the gate contact. The dielectric layer is located at a cell boundary of the second transistor structure.

As may be combined with the preceding paragraphs, the gate contact may contact the gate structure of the first transistor structure at a region between n-type and p-type transistors.

As may be combined with the preceding paragraphs, a first interconnect wiring level may be disposed over the second transistor structure, and a second interconnect wiring level may be disposed under the first transistor structure. Wires of the first interconnect wiring level can be spaced apart from each other at a first pitch, and wires of the second interconnect wiring level can be spaced apart from each other a second pitch greater than the first pitch. The first interconnect wiring level can be on a frontside of the semiconductor device, and the second interconnect wiring level can be on a backside of the semiconductor device. At least one contact may be disposed from the frontside of the semiconductor device to the backside of the semiconductor device, wherein the at least one contact connects a wire of the first interconnect wiring level with a wire of the second interconnect wiring level.

In another embodiment, a semiconductor device includes a first device layer, a second device layer stacked on the first device layer, and a plurality of gate isolation regions disposed through respective gate structures of the second device layer. The plurality of gate isolation regions overlap respective areas between adjacent transistors in the first device layer. A plurality of gate contacts are disposed through the plurality of gate isolation regions, wherein the plurality of gate contacts contact gate structures in the respective areas between the adjacent transistors in the first device layer.

As may be combined with the preceding paragraphs, the plurality of gate isolation regions may respectively include at least one dielectric layer disposed between a gate contact of the plurality of gate contacts and a gate structure of the second device layer. A plurality of additional gate isolation regions may be disposed through respective gate structures of the first device layer, wherein the plurality of additional gate isolation regions are offset from the plurality of gate isolation regions.

### BRIEF DESCRIPTION OF THE DRAWINGS

FIG. 1A depicts a cross-sectional view of a semiconductor structure taken across source/drain regions and illustrating a stacked transistor configuration, according to an embodiment of the invention.

FIG. 1B depicts a cross-sectional view of a semiconductor structure taken along gate structures and illustrating a stacked transistor configuration, according to an embodiment of the invention.

FIG. 2A depicts a cross-sectional view of a semiconductor structure taken across source/drain regions following middle-of-line (MOL) contact formation, according to an embodiment of the invention.

FIG. 2B depicts a cross-sectional view of a semiconductor structure taken along gate structures following MOL contact formation, according to an embodiment of the invention.

FIG. 3A depicts a cross-sectional view of a semiconductor structure taken across source/drain regions following back-end-of-line (BEOL) interconnect formation and carrier wafer bonding, according to an embodiment of the invention.

FIG. 3B depicts a cross-sectional view of a semiconductor structure taken along gate structures following BEOL interconnect formation and carrier wafer bonding, according to an embodiment of the invention.

FIG. 4A depicts a cross-sectional view of a semiconductor structure taken across source/drain regions following wafer flipping and semiconductor substrate removal, according to an embodiment of the invention.

FIG. 4B depicts a cross-sectional view of a semiconductor structure taken along gate structures following wafer flipping and semiconductor substrate removal, according to an embodiment of the invention.

FIG. 5A depicts a cross-sectional view of a semiconductor structure taken across source/drain regions following etch stop layer and remaining semiconductor substrate removal, backside ILD layer formation and planarization, according to an embodiment of the invention.

FIG. 5B depicts a cross-sectional view of a semiconductor structure taken along gate structures following etch stop layer and remaining semiconductor substrate removal, backside ILD layer formation and planarization, according to an embodiment of the invention.

FIG. 6A depicts a cross-sectional view of a semiconductor structure taken across source/drain regions following sacrificial placeholder layer removal, backside contact formation and planarization, according to an embodiment of the invention.

FIG. 6B depicts a cross-sectional view of a semiconductor structure taken along gate structures following sacrificial placeholder layer removal, backside contact formation and planarization, according to an embodiment of the invention.

FIG. 7A depicts a cross-sectional view of a semiconductor structure taken across source/drain regions following backside metallization layer formation, according to an embodiment of the invention.

FIG. 7B depicts a cross-sectional view of a semiconductor structure taken along gate structures following backside metallization layer formation, according to an embodiment of the invention.

FIG. 8A depicts a cross-sectional view of a semiconductor structure taken across source/drain regions following backside interconnect formation, according to an embodiment of the invention.

FIG. 8B depicts a cross-sectional view of a semiconductor structure taken along gate structures following backside interconnect formation, according to an embodiment of the invention.

### DETAILED DESCRIPTION

Illustrative embodiments of the invention may be described herein in the context of illustrative methods for forming deep via structures for stacked transistor devices, along with illustrative apparatus, systems and devices formed using such methods. However, it is to be understood that embodiments of the invention are not limited to the illustrative methods, apparatus, systems and devices but instead are more broadly applicable to other suitable methods, apparatus, systems and devices.

It is to be understood that the various features shown in the accompanying drawings are schematic illustrations that are not necessarily drawn to scale. Moreover, the same or similar reference numbers are used throughout the drawings to denote the same or similar features, elements, or structures, and thus, a detailed explanation of the same or similar features, elements, or structures will not be repeated for each of the drawings. Further, the terms “exemplary” and “illustrative” as used herein mean “serving as an example, instance, or illustration.” Any embodiment or design described herein as “exemplary” or “illustrative” is not to be construed as preferred or advantageous over other embodiments or designs.

A field-effect transistor (FET) is a transistor having a source, a gate, and a drain, and having action that depends on the flow of carriers (electrons or holes) along a channel that runs between the source and drain. Current through the channel between the source and drain may be controlled by a transverse electric field under the gate.

FETs are widely used for switching, amplification, filtering, and other tasks. FETs include metal-oxide-semiconductor (MOS) FETs (MOSFETs). Complementary MOS (CMOS) devices are widely used, where both n-type and p-type transistors (nFET and pFET) are used to fabricate logic and other circuitry. Source and drain regions of a FET are typically formed by adding dopants to target regions of a semiconductor body on either side of a channel, with the gate being formed above the channel. The gate includes a gate dielectric over the channel and a gate conductor over the gate dielectric. The gate dielectric is an insulator material that prevents large leakage current from flowing into the channel when voltage is applied to the gate conductor while allowing applied gate voltage to produce a transverse electric field in the channel.

Various techniques may be used to reduce the size of FETs. One technique is through the use of fin-shaped channels in FinFET devices. Before the advent of FinFET arrangements, CMOS devices were typically substantially planar along the surface of the semiconductor substrate, with the exception of the FET gate disposed over the top of the channel. FinFETs utilize a vertical channel structure, increasing the surface area of the channel exposed to the gate. Thus, in FinFET structures the gate can more effectively control the channel, as the gate extends over more than one side or surface of the channel. In some FinFET arrangements, the gate encloses three surfaces of the three-dimensional channel, rather than being disposed over just the top surface of a traditional planar channel.

Another technique useful for reducing the size of FETs is through the use of stacked nanosheet channels formed over a semiconductor substrate. Stacked nanosheets may be two-dimensional nanostructures, such as sheets having a thickness range on the order of 1 to 100 nanometers (nm). Nanosheets and nanowires are viable options for scaling to 7 nm and beyond. A general process flow for formation of a nanosheet stack involves selectively removing sacrificial layers, which may be formed of silicon germanium (SiGe) between sheets of channel material, which may be formed of silicon (Si).

For continued scaling (e.g., to 2.5 nm and beyond), next-generation stacked FET devices may be used. Next-generation stacked FET devices provide a complex gate-all-around (GAA) structure. Conventional GAA FETs, such as nanosheet FETs, may stack multiple p-type nanowires or nanosheets on top of each other in one device, and may stack multiple n-type nanowires or nanosheets on top of each other in another device. Next-generation stacked FET structures provide improved track height scaling, leading to structural gains (e.g., such as 30-40% structural gains for different types of devices, such as logic devices, static random-access memory (SRAM) devices, etc.). In next-generation stacked FET structures, n-type and p-type nanowires or nanosheets are stacked on each other, eliminating n-to-p separation bottlenecks and reducing the device area footprint. There is, however, a continued desire for further scaling and reducing the size of FETs.

As discussed above, various techniques may be used to reduce the size of FETs, including through the use of fin-shaped channels in FinFET devices, through the use of stacked nanosheet channels formed over a semiconductor substrate, and next-generation stacked FET devices.

Although embodiments of the present invention are discussed in connection with nanosheet stacks, the embodiments of the present invention are not necessarily limited thereto, and may similarly apply to nanowire stacks.

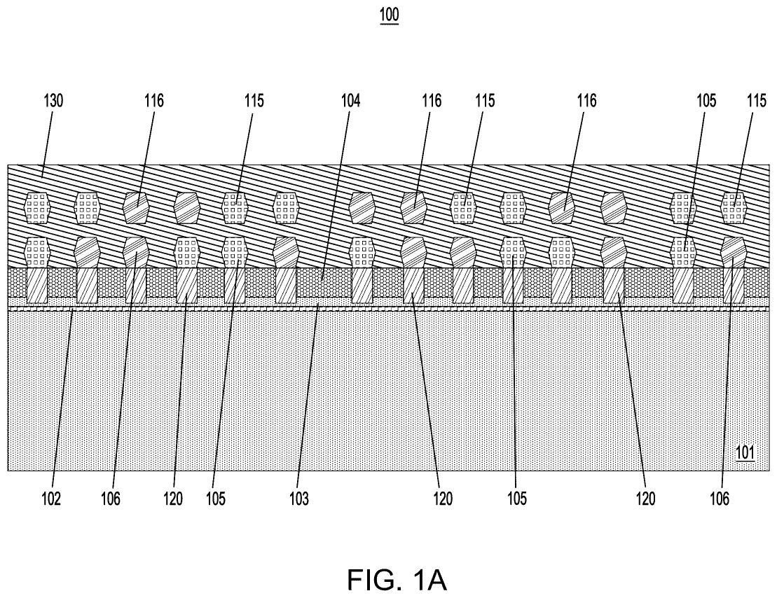

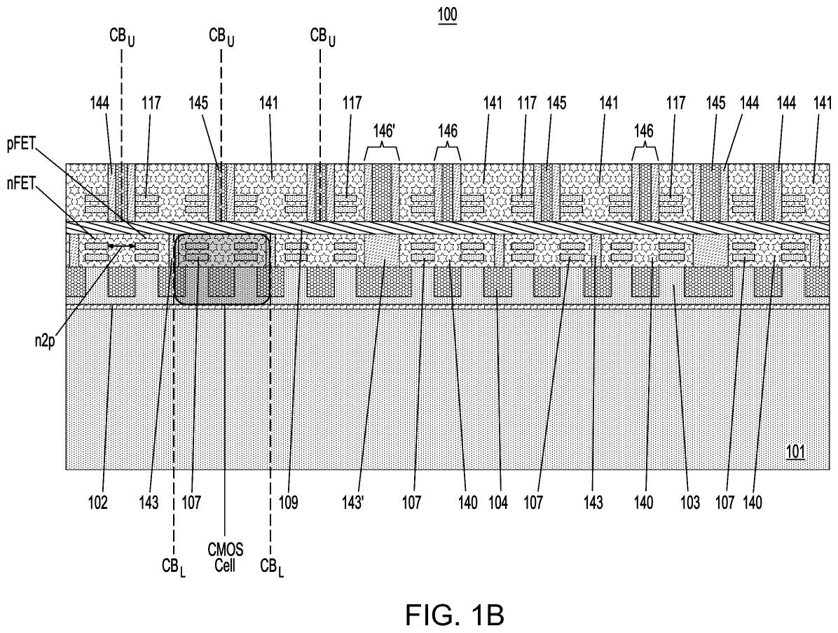

FIGS. 1A and 1B depict cross-sectional views of a semiconductor structure 100 taken across source/drain regions and along gate structures, respectively, and illustrating a stacked transistor configuration. Referring to the cross-sectional views in FIGS. 1A and 1B, a semiconductor structure 100 includes a stacked structure of a plurality of upper transistors (also referred to herein as “second transistors”) stacked on a plurality of lower transistors (also referred to herein as “first transistors”). The lower transistors are part of a lower device layer (also referred to herein as a “first device layer”) and the upper transistors are part of an upper device layer (also referred to herein as a “second device layer”). In illustrative embodiments, the upper and lower device layers can be CMOS device layers.

The lower and upper transistors include nanosheet transistors. For example, the lower transistors include a plurality of first channel layers 107 alternately stacked with and surrounded by first gate structures 140. The upper transistors include a plurality of second channel layers 117 alternately stacked with and surrounded by second gate structures 141. The lower transistors further include first n-type source/drain regions 105 and first p-type source/drain regions 106, and the upper transistors further include second n-type source/drain regions 115 and second p-type source/drain regions 116 stacked over the first n-type source/drain regions 105 and first p-type source/drain regions 106. A middle dielectric layer 109 is disposed between the first and second gate structures 140 and 141 to isolate the first and second gate structures 140 and 141 from each other. In an illustrative embodiment, the middle dielectric layer 109 includes an oxide such as, for example, silicon dioxide (SiO₂).

A first semiconductor substrate 101 and a second semiconductor substrate 103 include semiconductor material including, but not limited to, silicon, III-V, II-V compound semiconductor materials or other like semiconductor materials. In addition, multiple layers of the semiconductor materials can be used as the semiconductor material of the first and second semiconductor substrates 101 and 103. An etch stop layer 102 is formed on the first semiconductor substrate 101 between the first semiconductor substrate 101 and the second semiconductor substrate 103. In an illustrative embodiment, the etch stop layer 102 includes silicon germanium (SiGe) with, for example, a germanium concentration of about 30% (e.g., SiGe30) or SiO₂ and the first and second semiconductor substrates 101 and 103 include silicon.

According to one or more embodiments, the etch stop layer 102 is epitaxially grown on the first semiconductor substrate 101, the second semiconductor substrate 103 is epitaxially grown on the etch stop layer 102. The embodiments are not necessarily limited to the shown number of first and second channel layers 107 and 117, and there may be more or less layers in the same alternating configuration depending on design constraints with the first and second gate structures 140 and 141.

The terms “epitaxial growth and/or deposition” and “epitaxially formed and/or grown,” mean the growth of a semiconductor material (crystalline material) on a deposition surface of another semiconductor material (crystalline material), in which the semiconductor material being grown (crystalline over layer) has substantially the same crystalline characteristics as the semiconductor material of the deposition surface (seed material). In an epitaxial deposition process, the chemical reactants provided by the source gases are controlled, and the system parameters are set so that the depositing atoms arrive at the deposition surface of the semiconductor substrate with sufficient energy to move about on the surface such that the depositing atoms orient themselves to the crystal arrangement of the atoms of the deposition surface. Therefore, an epitaxially grown semiconductor material has substantially the same crystalline characteristics as the deposition surface on which the epitaxially grown material is formed.

The epitaxial deposition process may employ the deposition chamber of a chemical vapor deposition type apparatus, such as a metal-organic chemical vapor deposition (MOCVD), rapid thermal chemical vapor deposition (RTCVD), ultra-high vacuum chemical vapor deposition (UHVCVD), or a low-pressure chemical vapor deposition (LPCVD) apparatus. A number of different sources may be used for the epitaxial deposition of the in situ doped semiconductor material. In some embodiments, the gas source for the deposition of an epitaxially formed semiconductor material may include silicon (Si) deposited from silane, disilane, trisilane, tetrasilane, hexachlorodisilane, tetrachlorosilane, dichlorosilane, trichlorosilane, and combinations thereof. In other examples, when the semiconductor material includes germanium, a germanium gas source may be selected from the group consisting of germane, digermane, halogermane, dichlorogermane, trichlorogermane, tetrachlorogermane and combinations thereof. The temperature for epitaxial deposition typically ranges from 450° C. to 900° C. Although higher temperature typically results in faster deposition, the faster deposition may result in crystal defects and film cracking.

As used herein, “frontside or “first side” refers to a side on top of the second semiconductor substrate 103 and/or in front of, on top of or in an upward direction from the stacked structure of the upper nanosheet transistors stacked on the lower nanosheet transistors in the orientation shown in the cross-sectional figures. As used herein, “backside” or “second side” refers to a side below the semiconductor substrate 103 and/or behind, under, below or in a downward direction from the stacked structure of the upper nanosheet transistors stacked on the lower nanosheet transistors in the orientation shown in the cross-sectional figures (e.g., opposite the “frontside”).

Isolation regions 104 (e.g., shallow trench isolation (STI)) regions are formed between nanosheet stacks in recessed portions of the second semiconductor substrate 103. Isolation regions 104 including dielectric material fill in the recessed portions of the second semiconductor substrate 103. The dielectric material may include, for example, SiO₂, silicon nitride (SiN), silicon oxynitride (SiON), silicon-carbon-nitride (SiCN), boron nitride (BN), silicon boron nitride (SiBN), silicoboron carbonitride (SiBCN), silicon oxycarbonitride (SiOCN) and combinations thereof, and is deposited using deposition techniques such as, for example, chemical vapor deposition (CVD), plasma enhanced CVD (PECVD), radio-frequency CVD (RFCVD), physical vapor deposition (PVD), atomic layer deposition (ALD), molecular beam deposition (MBD), pulsed laser deposition (PLD), and/or liquid source misted chemical deposition (LSMCD).

Prior to formation of the first n-type source/drain regions 105, first p-type source/drain regions 106, second n-type source/drain regions 115 and second p-type source/drain regions 116, portions of the second semiconductor substrate 103 are removed, such that portions of the second semiconductor substrate 103 are recessed to create openings (e.g., “trenches”) in the second semiconductor substrate 103. Sacrificial placeholder layers 120 for backside source/drain contacts are formed in the trenches. In more detail, the trenches are filled with sacrificial placeholder layers 120 including, for example, SiGe, III-V semiconductor material or other semiconductor material. The sacrificial placeholder layers 120 are deposited in the trenches using deposition techniques such as, for example, epitaxial growth, CVD, PECVD, RFCVD, PVD, ALD, MBD, PLD, and/or LSMCD.

First n-type source/drain regions 105 and first p-type source/drain regions 106 are epitaxially grown between the nanosheet stacks corresponding to the lower transistors and second n-type source/drain regions 115 and second p-type source/drain regions 116 are epitaxially grown between the nanosheet stacks corresponding to the lower transistors. The first n-type source/drain regions 105 and first p-type source/drain regions 106 correspond to lower transistors formed by first channel layers 107 and first gate structures 140 and second n-type source/drain regions 115 and second p-type source/drain regions 116 correspond to upper transistors formed by second channel layers 117 and second gate structures 141. The first n-type source/drain regions 105 and first p-type source/drain regions 106 include epitaxial layers grown from sides of first channel layers 107 and/or from top surfaces of the sacrificial placeholder layers 120. As can be seen, the first n-type source/drain regions 105 and first p-type source/drain regions 106 are formed on and contact corresponding ones of underlying sacrificial placeholder layers 120. The second n-type source/drain regions 115 and second p-type source/drain regions 116 include epitaxial layers grown from sides of second channel layers 117.

Although not shown, side surfaces of respective ones of the first channel layers 107 contact a side surface of at least one adjacent first n-type source/drain region 105 or first p-type source/drain regions 106, and side surfaces of respective ones of the second channel layers 117 contact a side surface of at least one adjacent second n-type source/drain region 115 or second p-type source/drain region 116.

According to a non-limiting embodiment of the present invention, the conditions of the epitaxial growth process for the first n-type source/drain regions 105, first p-type source/drain regions 106, second n-type source/drain regions 115 and second p-type source/drain regions 116 are, for example, RTCVD epitaxial growth using SiH₄, SiH₂Cl₂, GeH₄, CH₃SiH₃, B₂H₆, PF₃, and/or H₂ gases with temperature and pressure ranges of about 450° C. to about 800° C., and about 5 Torr-about 300 Torr. In the case of n-type FETS (nFETs), the first and second n-type source/drain regions 105 and 115 can include silicon doped with n-type dopants including, for example, phosphorus (P), arsenic (As) and antimony (Sb). In the case of p-type FETS (pFETs), the first and second p-type source/drain regions 106 and 116 can include silicon doped with n-type dopants including, for example, boron (B), boron fluoride (BF₂), gallium (Ga), indium (In), and thallium (Tl).

An inter-layer dielectric (ILD) layer 130 is deposited to fill in portions on and around the first n-type source/drain regions 105, first p-type source/drain regions 106, second n-type source/drain regions 115 and second p-type source/drain regions 116. The ILD layer 130 is deposited using deposition techniques such as, for example, CVD, PECVD, RFCVD, PVD, ALD, MBD, PLD, and/or LSMCD, followed by a planarization process, such as, chemical mechanical planarization (CMP) to planarize the ILD layer 130. The ILD layer 130 may include, for example, SiO₂, SiOC, SiOCN or some other dielectric.

In illustrative embodiments, each of the first and second gate structures 140 and 141 includes a gate dielectric layer such as, for example, a high-K dielectric layer including, but not necessarily limited to, HfO₂ (hafnium oxide), ZrO₂ (zirconium dioxide), hafnium zirconium oxide, Al₂O₃ (aluminum oxide), and Ta₂O₅ (tantalum oxide). Examples of high-k materials also include, but are not limited to, metal oxides such as hafnium silicon oxynitride, lanthanum oxide, lanthanum aluminum oxide, zirconium oxide, zirconium silicon oxide, zirconium silicon oxynitride, tantalum oxide, titanium oxide, barium strontium titanium oxide, barium titanium oxide, strontium titanium oxide, yttrium oxide, aluminum oxide, lead scandium tantalum oxide, and lead zinc niobate. According to an embodiment, the first and second gate structures 140 and 141 each include a metal gate portion including a work-function metal (WFM) layer, including but not necessarily limited to, for a pFET, titanium nitride (TiN), tantalum nitride (TaN) or ruthenium (Ru), and for an nFET, TiN, titanium aluminum nitride (TiAlN), titanium aluminum carbon nitride (TiAlCN), titanium aluminum carbide (TiAlC), tantalum aluminum carbide (TaAlC), tantalum aluminum carbon nitride (TaAlCN) or lanthanum (La) doped TiN, TaN, which can be deposited on the gate dielectric layer. The metal gate portions can also each further include a gate metal layer including, but not necessarily limited to, metals, such as, for example, tungsten, cobalt, zirconium, tantalum, titanium, aluminum, ruthenium, copper, metal carbides, metal nitrides, transition metal aluminides, tantalum carbide, titanium carbide, tantalum magnesium carbide, or combinations thereof deposited on the WFM layer and the gate dielectric layer. It should be appreciated that various other materials may be used for the metal gate portions as desired.

Portions of the first and second gate structures 140 and 141 are removed where gate isolation regions (also referred to herein as “gate cut portions”) are to be formed. Referring to FIG. 1B, first gate isolation regions 143 are formed in the first device layer through portions of the first gate structures 140 over isolation regions 104, and second gate isolation regions 146 are formed in the second device layer through portions of the second gate structures 141. The second gate isolation regions 146 are offset with respect to the first gate isolation regions 143. In an illustrative embodiment, the first gate isolation regions 143 are disposed after respective pairs of nanosheet stacks including first channel layers 107 alternately stacked with and surrounded by first gate structures 140. In other words, respective pairs of nanosheet stacks including first channel layers 107 alternately stacked with and surrounded by first gate structures 140 are disposed between adjacent first gate isolation regions 143. In an illustrative embodiment, the second gate isolation regions 146 are formed between nanosheet stacks including the second channel layers 117 and second gate structures 141. As can be seen in FIG. 1B, in illustrative embodiments, the second gate isolation regions 146 contact sidewalls of opposing second channel layers 117 to form forksheet transistors. In a forksheet FET, an nFET and a pFET are integrated in the same structure, where a dielectric layer separates the nFET and pFET.

The first gate isolation regions 143 respectively include a single dielectric layer, and the second gate isolation regions 146 include each include a bi-layer dielectric portion. The bi-layers respectively include central dielectric layers 145 and liner dielectric layers 144. The central dielectric layers 145 include, for example, an oxide material (e.g., SiO₂), and the single dielectric layer of the first gate isolation regions 143 and the liner dielectric layers 144 include, for example, a nitride material (e.g., SiN, SiON, SiCN, BN, SiBN, SiBCN and/or SiOCN). The liner dielectric layers 144 are formed on side portions of and around the central dielectric layers 145.

As shown in FIG. 1B, the lower device level includes two additional first gate isolation regions 143′ aligned with two additional second gate isolation regions 146′ in the second device layer. The two additional first gate isolation regions 143′ and the two additional second gate isolation regions 146′ are configured similarly to the first gate isolation regions 143 and the second gate isolation regions 146 with a single dielectric layer and a bi-layer dielectric portion including central dielectric layers 145 and liner dielectric layers 144.

The dielectric materials of the first and second gate isolation regions 143 and 146 and of the additional first and second gate isolation regions 143′ and 146′ are deposited using deposition techniques such as, for example, CVD, PECVD, RFCVD, PVD, ALD, MBD, PLD, and/or LSMCD, followed by a planarization process, such as, CMP. The dielectric material of the central dielectric layers 145 may include, but is not necessarily limited to, SiOₓ, and the dielectric material of the liner dielectric layers 144 may include, but is not necessarily limited to, SiN, SiON, SiCN, BN, SiBN, SiBCN and/or SiOCN.

As can be seen in FIG. 1B, cell boundaries CB_{U} caused by the second gate isolation regions 146 in the upper device level are offset with respect to cell boundaries CB_{L} caused by the first gate isolation regions 143 in the lower device level. As a result, cell boundaries CB_{U} of the upper device layer overlap with N2P spaces (n2p) of the lower device layer. The N2P spaces (n2p) are spaces between n-type and p-type portions (e.g., nFET and pFET portions) of a CMOS device (CMOS cell). FIG. 1B illustrates a CMOS cell.

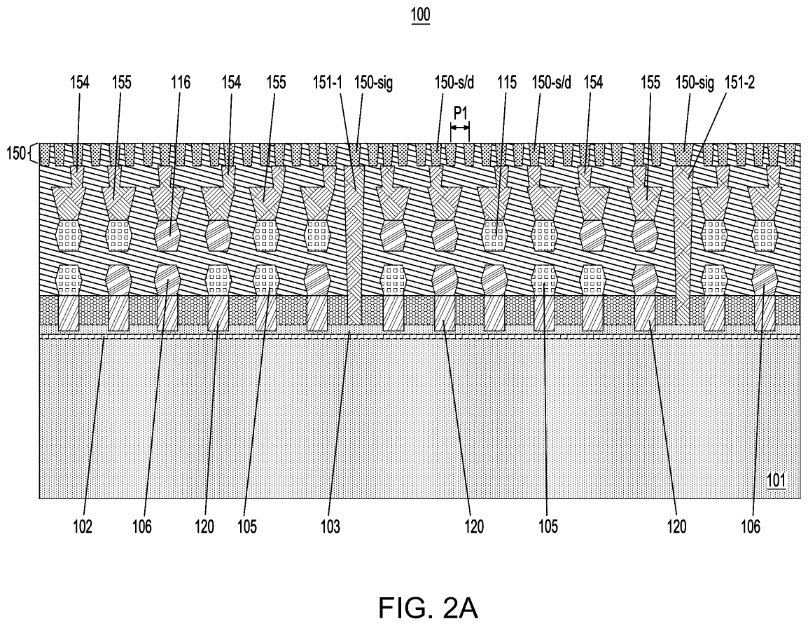

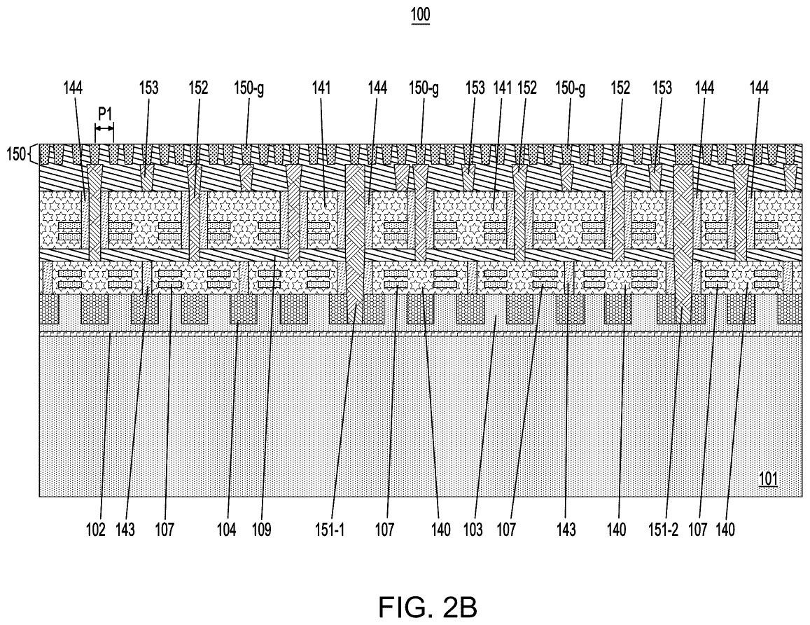

In illustrative embodiments, referring to FIGS. 2A and 2B, using masks (e.g., organic planarization layers, hardmasks, etc.), exposed portions of the ILD layer 130 and underlying portions of the central dielectric layers 145 of the second gate isolation regions 146 and of the middle dielectric layer 109 are removed to expose underlying portions of the first gate structures 140 of the first device layer. In addition, exposed portions of the ILD layer 130 and underlying portions of central dielectric layers 145 of the additional second gate isolation regions 146′, of the middle dielectric layer 109, of the additional first gate isolation regions 143′ and of corresponding isolation regions 104 are removed down to the second semiconductor substrate 103.

The selective removal of the exposed ILD layer 130 and portions of the central dielectric layers 145, the middle dielectric layer 109, the additional first gate isolation regions 143′ and corresponding isolation regions 104 is performed using, for example, by a plasma dry etch process.

Conductive material is deposited on the first gate structures 140 in openings formed by the removal of exposed portions of the ILD layer 130 and underlying portions of the central dielectric layers 145 of the second gate isolation regions 146 and of the middle dielectric layer 109. The deposition of the conductive material in the openings forms frontside deep gate contacts 152, which extend through the remaining portions of the second gate isolation regions 146 of the second device level to land on and contact respective first gate structures 140 of transistors in the first device level. The respective first gate structures 140 are contacted in respective areas between adjacent transistors in the first device layer (e.g., in N2P spaces).

The remaining portions of the second gate isolation regions 146 respectively include the liner dielectric layers 144, which are interposed between the frontside deep gate contacts 152 and respective groups of stacked second channel layers 117 contacting the liner dielectric layers 144. In illustrative embodiments, the liner dielectric layers 144 contacting the second channel layers 117 results in forksheet devices with better scaling capability than gate-all-around (GAA) devices. Alternatively, portions of the second gate structures 141 may be disposed between the second channel layers and the liner dielectric layers 144 resulting in GAA devices, which may have better gate control than the forksheet devices, but less scaling capability. The liner dielectric layers 144 isolate the upper transistors (e.g., second channel layers 117 and second gate structures 141) from the frontside deep gate contacts 152.

Conductive material is deposited in openings formed by the removal of exposed portions of the ILD layer 130 and underlying portions of the central dielectric layers 145 of the additional second gate isolation regions 146′, the middle dielectric layer 109, additional first gate isolation regions 143′ and isolation regions 104. The deposition of the conductive material in these openings forms deep contacts 151-1 and 151-2 (also referred to herein as “deep vias”) (collectively, “deep contacts 151”), which extend through the upper and lower device layers (e.g., through first and second gate structures 140 and 141) onto the second semiconductor substrate 103. The remaining portions of the additional first gate isolation regions 143′ and the additional second gate isolation regions 146′ are interposed between the deep contacts 151 and the first and second gate structures 140 and 141. The remaining portions of the additional first gate isolation regions 143′ include the remaining dielectric material of the additional first gate isolation regions 143′.

Conductive material is deposited on the second gate structures 141 in openings formed by the removal of exposed portions of the ILD layer 130 to form frontside shallow gate contacts 153, which land on and contact respective second gate structures 141 of transistors in the second device level.

Conductive material is deposited on the second n-type source/drain regions 115 and second p-type source/drain regions 116 in openings formed by the removal of exposed portions of the ILD layer 130 to form frontside source/drain vias 154 and frontside source/drain contacts 155, which land on and contact respective second n-type source/drain regions 115 or second p-type source/drain regions 116. As can be seen in FIG. 2A, the frontside source/drain vias 154 have a smaller width in the left and right direction in the cross-sectional view of FIG. 2A than that of the frontside source/drain contacts 155.

A frontside interconnect wiring level including a plurality of wires 150 is formed in the ILD layer 130 over the deep contacts 151, frontside deep gate contacts 152, frontside shallow gate contacts 153, frontside source/drain vias 154 and frontside source/drain contacts 155. The wires 150 are spaced apart from each other at a pitch P1. Respective frontside source/drain voltage wires 150-s/d carrying source/drain voltages (e.g., Vss or Vdd) contact respective ones of the frontside source/drain vias 154. Respective frontside gate voltage wires 150-g carrying gate voltages contact respective ones of the frontside deep gate contacts 152 or frontside shallow gate contacts 153. As explained in more detail herein below, respective frontside signal wires 150-sig contact respective ones of the deep contacts 151, which connect to respective backside signal wires in a backside interconnect wiring level. In illustrative embodiments, the frontside signal wires 150-sig transmit gate input signals or other signals for lower transistors of a first (lower) device level. For example, connections that are not wired to power (e.g., Vdd or Vss) are for signals.

Conductive material of the wires 150, deep contacts 151, frontside deep gate contacts 152, frontside shallow gate contacts 153, frontside source/drain vias 154 and frontside source/drain contacts 155 includes, for example, a silicide layer, such as Ni, Ti, NiPt, etc., a metal adhesion layer, such as TiN, and a conductive metal fill layer, such as W, Al, Co, Ru, Cu, etc., and can be deposited using, for example, a deposition technique such as CVD, PECVD, RFCVD, PVD, ALD, MBD, PLD, LSMCD, sputtering and/or plating, followed by a planarization process such as, CMP to remove excess portions of the metal layers from on top of the ILD layer 130. In some embodiments, the silicide layer and/or metal adhesion layer can be omitted.

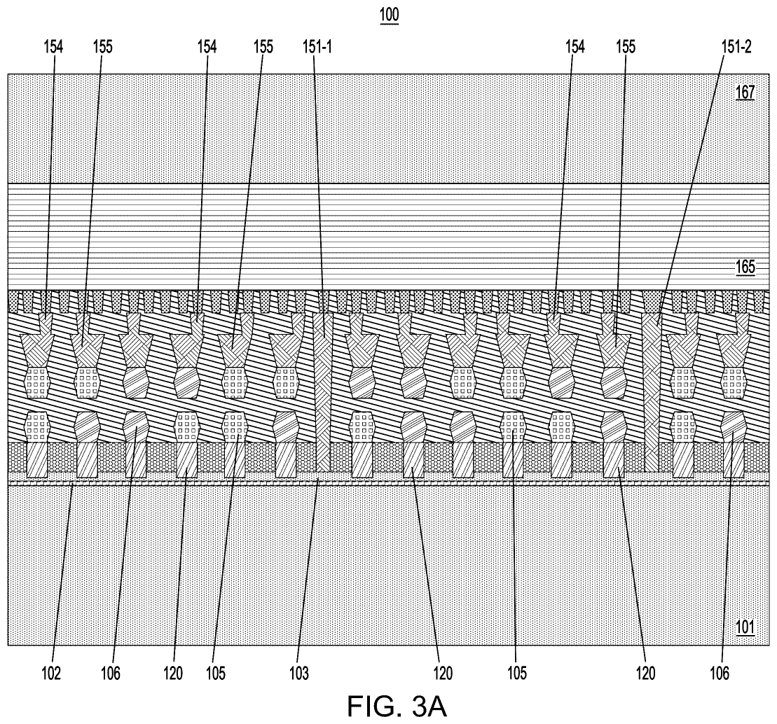

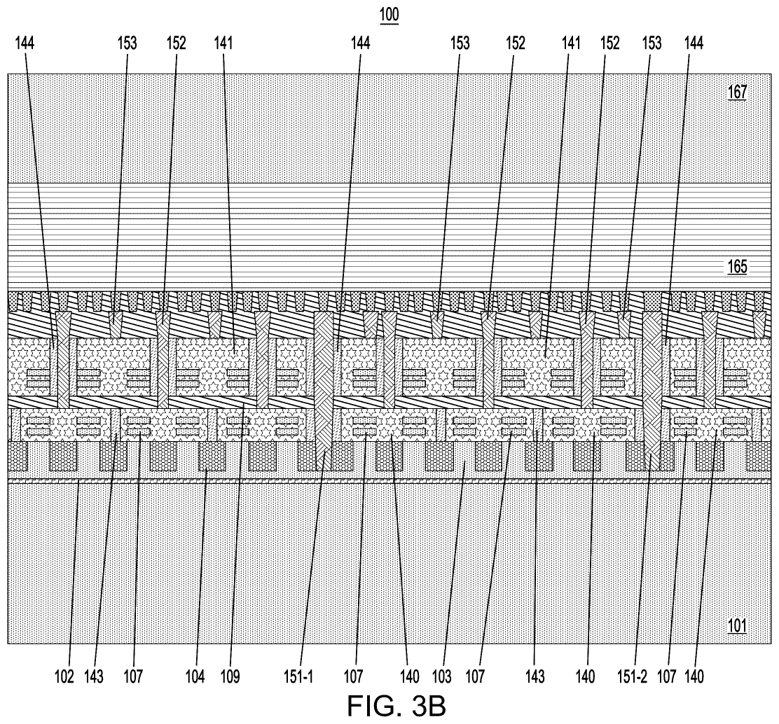

Referring to FIGS. 3A and 3B, frontside BEOL interconnects 165 are formed on the structure of FIGS. 2A and 2B. The wires 150 of the frontside interconnect wiring level (e.g., frontside source/drain voltage wires 150-s/d, frontside gate voltage wires 150-g and frontside signal wires 150-sig) extend through the ILD layer 130 from the frontside BEOL interconnects 165 to deliver voltages to deep contacts 151, frontside deep gate contacts 152, frontside shallow gate contacts 153, frontside source/drain vias 154 and frontside source/drain contacts 155. For example, frontside source/drain voltage wires 150-s/d respectively connect the frontside BEOL interconnects 165 with frontside source/drain vias and contacts 154 and 155. Frontside gate voltage wires 150-g respectively connect the frontside BEOL interconnects 165 with frontside deep gate contacts 152 or frontside shallow gate contacts 153. Frontside signal wires 150-sig respectively connect the frontside BEOL interconnects 165 with deep contacts 151.

A carrier wafer 167 is bonded to the frontside BEOL interconnects 165. The frontside BEOL interconnects 165 include various BEOL interconnect structures which may electrically connect to the deep contacts 151, frontside deep gate contacts 152, frontside shallow gate contacts 153, frontside source/drain vias 154 and frontside source/drain contacts 155. The carrier wafer 167 may be formed of materials similar to that of the first and second semiconductor substrates 101 and 103, and may be formed over the frontside BEOL interconnects 165 using a wafer bonding process, such as dielectric-to-dielectric bonding.

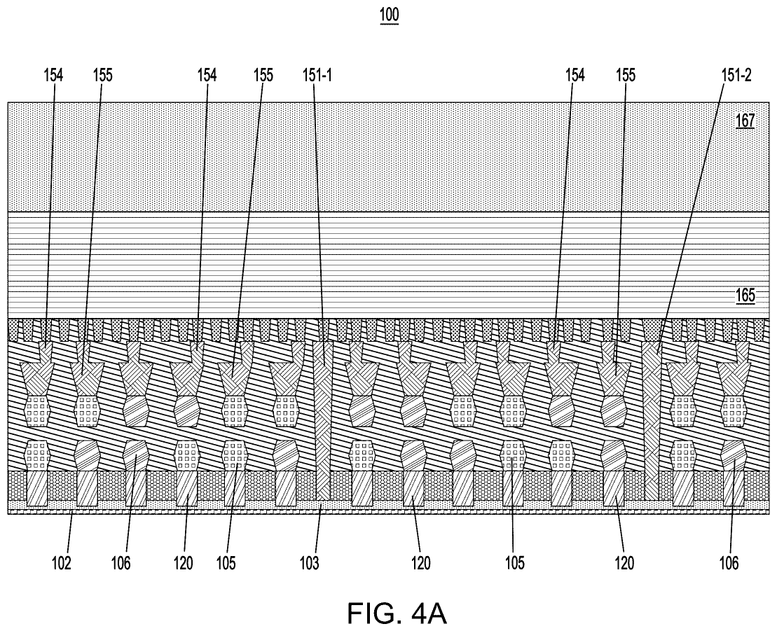

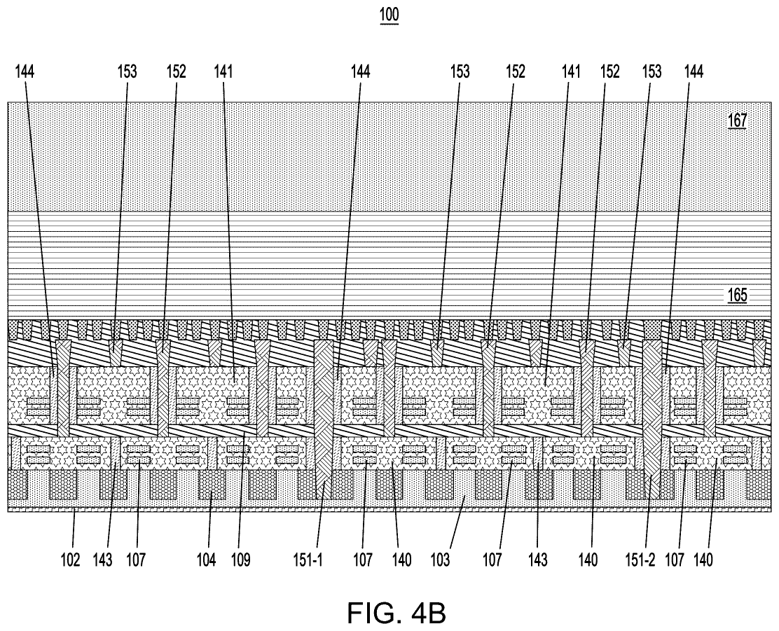

Referring to FIGS. 4A and 4B, using the carrier wafer 167, the semiconductor structure 100 may be “flipped” (e.g., rotated 180 degrees) so that the structure is inverted. In addition, the first semiconductor substrate 101 is removed from the backside of the semiconductor structure 100. The removal process, which includes etching of the first semiconductor substrate 101, stops at the etch stop layer 102. For example, the first semiconductor substrate 101 is selectively etched with an etchant that selectively etches silicon with respect to a material of the etch stop layer 102 (e.g., SiGe).

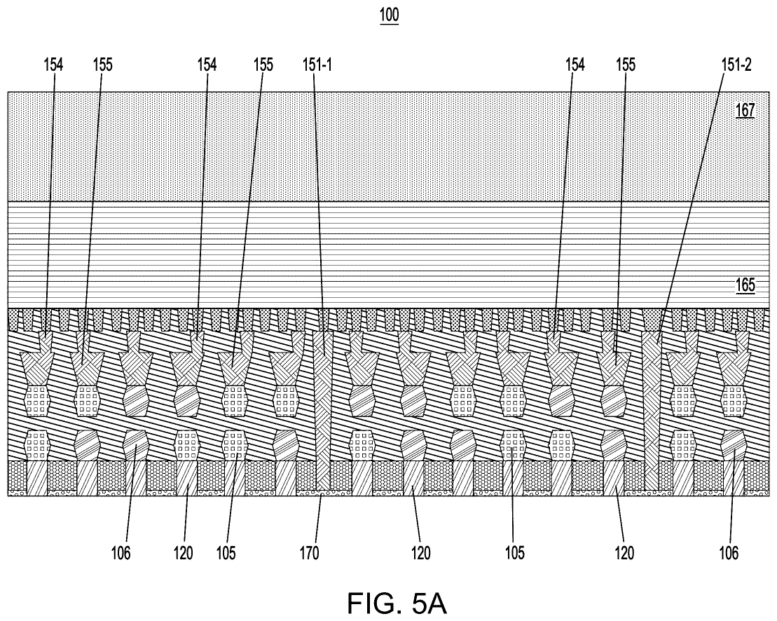

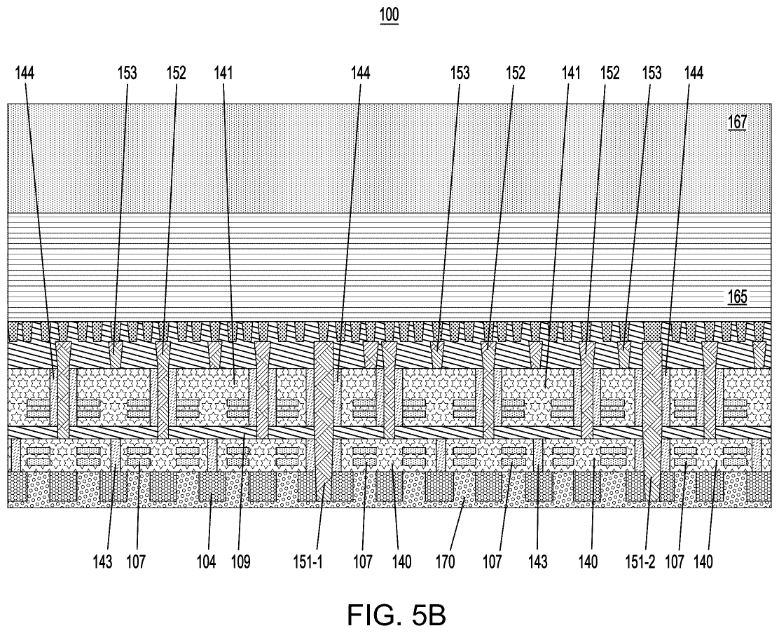

Referring to FIGS. 5A and 5B, the etch stop layer 102 and the second semiconductor substrate 103 (e.g., silicon layer) are selectively removed from the semiconductor structure 100 with respect to the sacrificial placeholder layers 120 and the isolation regions 104. As shown in FIGS. 5A and 5B, the etch stop layer 102 is removed, followed by removal of the second semiconductor substrate 103, wherein portions of the isolation regions 104, the sacrificial placeholder layers 120, first gate structures 140 and deep contacts 151 are exposed. Etching processes for removal of the etch stop layer 102 include, for example, IBE by Ar/CHF₃ based chemistry.

A backside ILD layer 170 is deposited to fill in areas formerly occupied by the second semiconductor substrate 103. The backside ILD layer 170 is deposited using deposition techniques such as, for example, CVD, PECVD, RFCVD, PVD, ALD, MBD, PLD, and/or LSMCD, followed by a planarization process, such as, CMP to remove excess portions of the backside ILD layer 170 deposited on top of the sacrificial placeholder layers 120 so that the backside ILD layer 170 is coplanar with surfaces of the sacrificial placeholder layers 120. The surfaces of the sacrificial placeholder layers 120 are exposed following the CMP process. The backside ILD layer 170 may include, for example, SiOx, SiOC, SiOCN or some other dielectric.

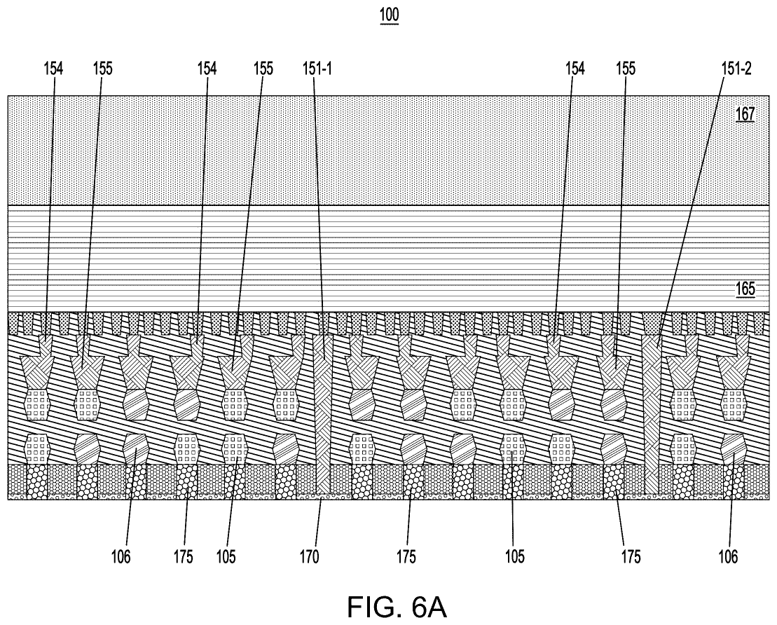

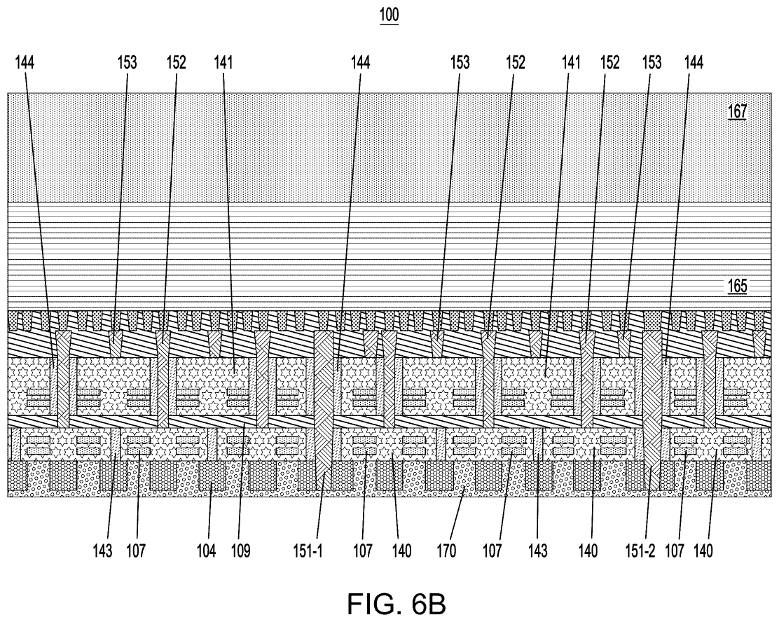

Referring to FIGS. 6A and 6B, the sacrificial placeholder layers 120 are selectively removed to create openings exposing backside portions of the first n-type source/drain regions 105 and first p-type source/drain regions 106. The sacrificial placeholder layers 120 are removed using, for example, a selective dry or wet etch process. Backside source/drain contacts 175 are formed in the backside ILD layer 170 in the openings left by the removal of the sacrificial placeholder layers 120. Metal layers are deposited in the openings to form the backside source/drain contacts 175. The metal layers include, for example, a silicide layer, such as Ni, Ti, NiPt, etc., a metal adhesion layer, such as TiN, and a conductive metal fill layer, such as W, Al, Co, Ru, Cu, etc., and can be deposited using, for example, a deposition technique such as CVD, PECVD, RFCVD, PVD, ALD, MBD, PLD, LSMCD, sputtering and/or plating, followed by a planarization process such as, CMP to remove excess portions of the metal layers from on top of the backside ILD layer 170. In some embodiments, the silicide layer and/or metal adhesion layer can be omitted.

The backside source/drain contacts 175 contact respective backsides of the first n-type source/drain regions 105 and first p-type source/drain regions 106 in the lower device level. The backside source/drain contacts 175 extend through the backside ILD layer 170 and on sides of the isolation regions 104 to land on and contact the backsides of the corresponding first n-type source/drain regions 105 and first p-type source/drain regions 106.

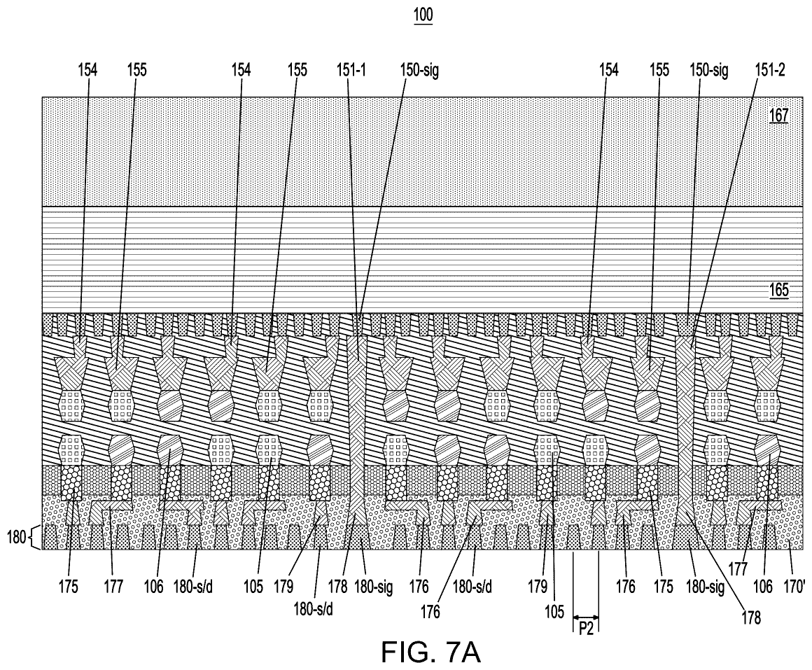

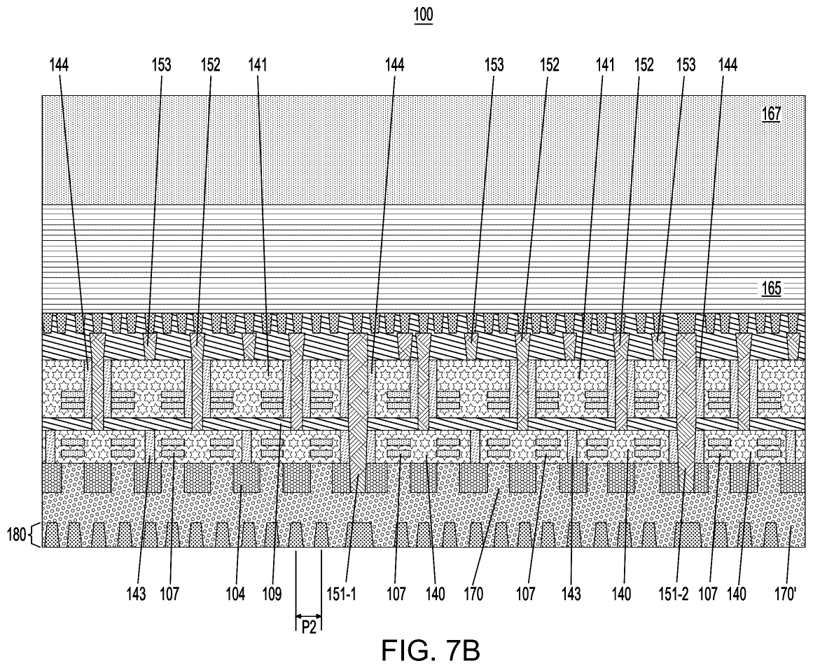

Referring to FIGS. 7A and 7B, additional backside ILD material is deposited to form an additional backside ILD layer 170′ on the backside ILD layer 170. In illustrative embodiments, using masks (e.g., organic planarization layers, hardmasks, etc.), exposed portions of the additional backside ILD layer 170′ and in areas corresponding to the deep contacts 151, underlying portions of the backside ILD layer 170 are removed. Given the configuration of some of the contacts (e.g., intermediate backside contacts 177), the additional backside ILD layer 170′ can be deposited in stages, where contacts are formed and then further backside dielectric material is deposited to form remaining portions of the additional backside ILD layer 170′ in which other contacts or vias (e.g., first backside vias 176, second backside vias 178 and third backside vias 179) or wires (e.g., wires 180) are subsequently formed.

A backside interconnect wiring level including a plurality of wires 180 is formed in the additional backside ILD layer 170′ under the backside source/drain contacts 175, first backside vias 176, second backside vias 178, third backside vias 179 and the intermediate backside contacts 177. The wires 180 are spaced apart from each other at a pitch P2, which is greater than the pitch P1.

Respective backside source/drain voltage wires 180-s/d carrying source/drain voltages (e.g., Vss or Vdd) contact respective ones of the first backside vias 176 or third backside vias 179. The first backside vias 176 contact the intermediate backside contacts 177. Respective ones of the intermediate backside contacts 177 contact a backside source/drain contact 175 that is not aligned (e.g., misaligned) with a corresponding backside source/drain voltage wire 180-s/d. The corresponding backside source/drain voltage wire 180-s/d is also connected to the intermediate backside contact 177 (through a first backside via 176) and provides a source/drain voltage to the misaligned backside source/drain contact 175. An intermediate backside contact 177 includes a first portion overlapping a first n-type source/drain region 105 or first p-type source/drain region 106 and its corresponding backside source/drain contact 175 and a second portion overlapping a backside source/drain voltage wire 180-s/d and its corresponding first backside via 176. The intermediate backside contacts 177 and first backside vias 176 are used when the backside source/drain voltage wires 180-s/d are not aligned with the first n-type source/drain regions 105 or first p-type source/drain regions 106 to which the backside source/drain voltage wires 180-s/d are supplying a source/drain voltage.

The third backside vias 179 connect backside source/drain voltage wires 180-s/d which are aligned with the first n-type source/drain regions 105 or first p-type source/drain regions 106 to which the backside source/drain voltage wires 180-s/d are supplying a source/drain voltage. As can be seen, a third backside via 179 and its corresponding backside source/drain voltage wire 180-s/d are under and overlap with their corresponding backside source/drain contact 175 and first n-type source/drain region 105 or first p-type source/drain region 106.

Respective backside signal wires 180-sig contact respective ones of the deep contacts 151 through the second backside vias 178. As noted herein above, each of the deep contacts 151 extends through the semiconductor structure 100 from a frontside to a backside (or from a backside to a frontside) to connect a frontside signal wire 150-sig of the frontside interconnect wiring level with a backside signal wire 180-sig of the backside interconnect wiring level. In illustrative embodiments, the frontside signal wires 150-sig and backside signal wires 180-sig transmit gate input signals for lower transistors of the lower device level.

Conductive material of the wires 180, backside source/drain contacts 175, first backside vias 176, second backside vias 178, third backside vias 179 and the intermediate backside contacts 177 includes, for example, a silicide layer, such as Ni, Ti, NiPt, etc., a metal adhesion layer, such as TiN, and a conductive metal fill layer, such as W, Al, Co, Ru, Cu, etc., and can be deposited using, for example, a deposition technique such as CVD, PECVD, RFCVD, PVD, ALD, MBD, PLD, LSMCD, sputtering and/or plating, followed by a planarization process such as, CMP to remove excess portions of the metal layers from on top of the backside ILD layer 170 or additional backside ILD layer 170′. In some embodiments, the silicide layer and/or metal adhesion layer can be omitted.

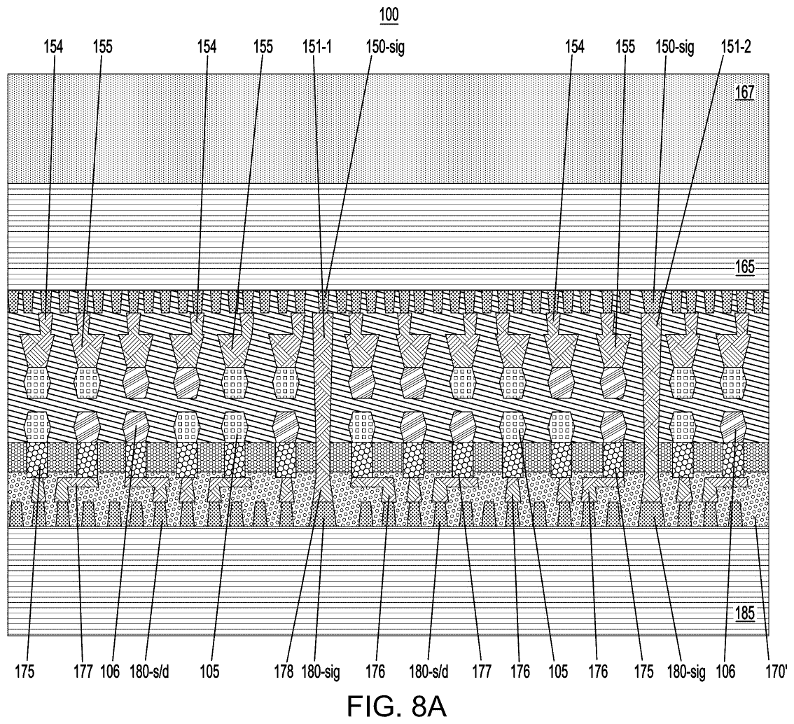

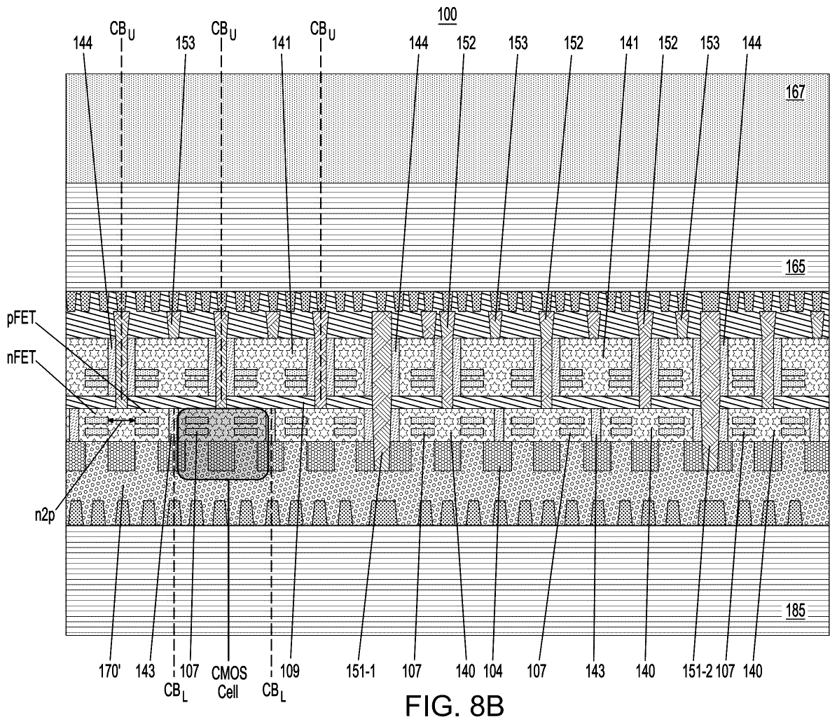

Referring to FIGS. 8A and 8B, backside power delivery network (BSPDN) 185 (also referred to herein as backside interconnects) is formed on the additional backside ILD layer 170′ and on the wires 180 of the backside interconnect wiring level. The BSPDN 185 includes various BSPDN structures such as, but not necessarily limited to, interconnects in a power supply path from voltage regulator modules (VRMs) to circuits. The interconnects can include, for example, power and ground planes in circuit boards, cables, connectors and capacitors associated with a power supply. Backside power delivery prevents BEOL routing congestion, resulting in power performance benefits.

Referring to FIG. 1B and FIG. 8B, after removal of the central dielectric layers 145 from the second gate isolation regions 146 in the upper device level and replacement with frontside deep gate contacts 152, cell boundaries CB_{U} include the liner dielectric layers 144 and frontside deep gate contacts 152. The cell boundaries CB_{U} of the upper device layer including the liner dielectric layers 144 and frontside deep gate contacts 152 are offset with respect to cell boundaries CB_{L} caused by the first gate isolation regions 143 in the lower device level. As a result, cell boundaries CB_{U} of the upper device layer overlap with N2P spaces (n2p) of the lower device layer. The N2P spaces are spaces between nFET and pFET portions of a CMOS device (CMOS cell). The frontside deep gate contacts 152, which extend through the remaining portions of the second gate isolation regions 146 of the second device level land on and contact respective first gate structures 140 of transistors in the first device level in respective areas between adjacent transistors in the first device layer (e.g., in the N2P spaces (n2p)).

In one embodiment, a semiconductor device includes a plurality of first transistors, a plurality of second transistors stacked on the plurality of first transistors, a plurality of gate isolation regions disposed through respective gate structures of the plurality of second transistors, and a plurality of gate contacts disposed through the plurality of gate isolation regions. The plurality of gate contacts contact respective gate structures of the plurality of first transistors. Respective ones of the plurality of gate isolation regions are located at respective cell boundaries of the plurality of second transistors.

The plurality of gate contacts may contact the respective gate structures of the plurality of first transistors at respective regions between n-type and p-type transistors. The respective cell boundaries of the plurality of second transistors may be offset with respect to respective cell boundaries of the plurality of first transistors. One or more of the plurality of second transistors may include a forksheet transistor.

The semiconductor device may include a first interconnect wiring level on a first side of a stacked structure including the plurality of second transistors stacked on the plurality of first transistors, and a second interconnect wiring level on a second side of the stacked structure opposite the first side. Wires of the first interconnect wiring level can be spaced apart from each other at a first pitch, and wires of the second interconnect wiring level are spaced apart from each other a second pitch greater than the first pitch. The first side of the stacked structure may be on a frontside of the semiconductor device, and the second side of the stacked structure may be on a backside of the semiconductor device. At least one contact may be disposed from the first side of the stacked structure to the second side of the stacked structure, wherein the at least one contact connects a wire of the first interconnect wiring level with a wire of the second interconnect wiring level.

A source/drain region of at least one of the first transistors can be connected to a wire of the second interconnect wiring level, wherein the wire of the second interconnect wiring level is misaligned with the source/drain region. The source/drain region may be connected to the wire through a contact having a first portion overlapping the source/drain region and a second portion overlapping the wire.

The plurality of first transistors and the plurality of second transistors may include a plurality of nanosheet transistors respectively including a plurality of stacked channel regions. The plurality of gate isolation regions may respectively include at least one dielectric layer, and respective ones of the plurality of stacked channel regions in one or more of the plurality of second transistors may contact the at least one dielectric layer.

The plurality of gate isolation regions may respectively include at least one dielectric layer disposed between a gate contact of the plurality of gate contacts and a gate structure of a second transistor of the plurality of second transistors. A plurality of additional gate isolation regions may be disposed through respective gate structures of the plurality of first transistors, wherein the plurality of additional gate isolation regions are offset from the plurality of gate isolation regions. One or more of the plurality of second transistors may include a forksheet transistor.

In another embodiment, a semiconductor device includes a first transistor structure, a second transistor structure stacked on the first transistor structure, and a gate contact disposed through a gate structure of the second transistor structure. The gate contact contacts a gate structure of the first transistor structure, and is isolated from the gate structure of the second transistor structure by a dielectric layer disposed on sides of the gate contact. The dielectric layer is located at a cell boundary of the second transistor structure.

The gate contact may contact the gate structure of the first transistor structure at a region between n-type and p-type transistors.

A first interconnect wiring level may be disposed over the second transistor structure, and a second interconnect wiring level may be disposed under the first transistor structure. Wires of the first interconnect wiring level can be spaced apart from each other at a first pitch, and wires of the second interconnect wiring level can be spaced apart from each other a second pitch greater than the first pitch. The first interconnect wiring level can be on a frontside of the semiconductor device, and the second interconnect wiring level can be on a backside of the semiconductor device. At least one contact may be disposed from the frontside of the semiconductor device to the backside of the semiconductor device, wherein the at least one contact connects a wire of the first interconnect wiring level with a wire of the second interconnect wiring level.

A source/drain region of the first transistor structure can be connected to a wire of the second interconnect wiring level, and the wire of the second interconnect wiring level may be misaligned with the source/drain region. The source/drain region may be connected to the wire through a contact having a first portion overlapping the source/drain region and a second portion overlapping the wire.

In another embodiment, a semiconductor device includes a first device layer, a second device layer stacked on the first device layer, and a plurality of gate isolation regions disposed through respective gate structures of the second device layer. The plurality of gate isolation regions overlap respective areas between adjacent transistors in the first device layer. A plurality of gate contacts are disposed through the plurality of gate isolation regions, wherein the plurality of gate contacts contact gate structures in the respective areas between the adjacent transistors in the first device layer.

The plurality of gate isolation regions may respectively include at least one dielectric layer disposed between a gate contact of the plurality of gate contacts and a gate structure of the second device layer. A plurality of additional gate isolation regions may be disposed through respective gate structures of the first device layer, wherein the plurality of additional gate isolation regions are offset from the plurality of gate isolation regions.

Semiconductor devices and methods for forming the same in accordance with the above-described techniques can be employed in various applications, hardware, and/or electronic systems. Suitable hardware and systems for implementing embodiments of the invention may include, but are not limited to, personal computers, communication networks, electronic commerce systems, portable communications devices (e.g., cell and smart phones), solid-state media storage devices, functional circuitry, etc. Systems and hardware incorporating the semiconductor devices are contemplated embodiments of the invention. Given the teachings provided herein, one of ordinary skill in the art will be able to contemplate other implementations and applications of embodiments of the invention.

In some embodiments, the above-described techniques are used in connection with semiconductor devices that may require or otherwise utilize, for example, CMOSs, MOSFETs, and/or FinFETs. By way of non-limiting example, the semiconductor devices can include, but are not limited to CMOS, MOSFET, and FinFET devices, and/or semiconductor devices that use CMOS, MOSFET, and/or FinFET technology.

Various structures described above may be implemented in integrated circuits. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher-level carrier) or in a multichip package (such as a ceramic carrier that has either or both surface interconnections or buried interconnections). In any case the chip is then integrated with other chips, discrete circuit elements, and/or other signal processing devices as part of either: (a) an intermediate product, such as a motherboard, or (b) an end product. The end product can be any product that includes integrated circuit chips, ranging from toys and other low-end applications to advanced computer products having a display, a keyboard or other input device, and a central processor.

As noted above, the illustrative embodiments provide structures for and techniques for forming deep vias for stacked transistor devices to connect frontside interconnect wiring levels with backside interconnect wiring levels. For example, wires of a frontside interconnect wiring level (e.g., wires 150) can have a smaller pitch and, therefore, more wires than wires of a backside interconnect wiring level (e.g., wires 180). A stacked device architecture (e.g., stacked CMOS architecture) uses deep vias (also referred to herein as deep contacts) to connect wires of a frontside interconnect wiring level with wires of a backside interconnect wiring level so that input signals (e.g., gate input signals) can be transmitted from the frontside interconnect wiring level to lower level devices of the stacked device architecture.

As an additional advantage, the illustrative embodiments provide structures for and techniques for forming gate contacts disposed through gate structures of an upper transistor structure, wherein the gate contacts contact gate structures of a lower transistor structure. Each of the gate contacts (referred to herein as deep gate contacts) are isolated from a gate structure of the upper transistor structure by a dielectric layer disposed on sides of the gate contact.

It should be understood that the various layers, structures, and regions shown in the figures are schematic illustrations that are not drawn to scale. In addition, for ease of explanation, one or more layers, structures, and regions of a type commonly used to form semiconductor devices or structures may not be explicitly shown in a given figure. This does not imply that any layers, structures, and regions not explicitly shown are omitted from the actual semiconductor structures. Furthermore, it is to be understood that the embodiments discussed herein are not limited to the particular materials, features, and processing steps shown and described herein. In particular, with respect to semiconductor processing steps, it is to be emphasized that the descriptions provided herein are not intended to encompass all of the processing steps that may be required to form a functional semiconductor integrated circuit device. Rather, certain processing steps that are commonly used in forming semiconductor devices, such as, for example, wet cleaning and annealing steps, are purposefully not described herein for economy of description.

Moreover, the same or similar reference numbers are used throughout the figures to denote the same or similar features, elements, or structures, and thus, a detailed explanation of the same or similar features, elements, or structures are not repeated for each of the figures. It is to be understood that the terms “approximately” or “substantially” as used herein with regard to thicknesses, widths, percentages, ranges, temperatures, times and other process parameters, etc., are meant to denote being close or approximate to, but not exactly. For example, the term “approximately” or “substantially” as used herein implies that a small margin of error is present, such as ±5%, preferably less than 2% or 1% or less than the stated amount.

In the description above, various materials, dimensions and processing parameters for different elements are provided. Unless otherwise noted, such materials are given by way of example only and embodiments are not limited solely to the specific examples given. Similarly, unless otherwise noted, all dimensions and process parameters are given by way of example and embodiments are not limited solely to the specific dimensions or ranges given.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor device comprising:
a plurality of first transistors;
a plurality of second transistors stacked on the plurality of first transistors;
a plurality of gate isolation regions disposed through respective gate structures of the plurality of second transistors; and
a plurality of gate contacts disposed through the plurality of gate isolation regions, wherein the plurality of gate contacts contact respective gate structures of the plurality of first transistors;
wherein respective ones of the plurality of gate isolation regions are located at respective cell boundaries of the plurality of second transistors.

2. The semiconductor device of claim 1, wherein the plurality of gate contacts contact the respective gate structures of the plurality of first transistors at respective regions between n-type and p-type transistors.

3. The semiconductor device of claim 1, wherein the respective cell boundaries of the plurality of second transistors are offset with respect to respective cell boundaries of the plurality of first transistors.

4. The semiconductor device of claim 1, wherein one or more of the plurality of second transistors comprises a forksheet transistor.

5. The semiconductor device of claim 1, further comprising:
a first interconnect wiring level on a first side of a stacked structure comprising the plurality of second transistors stacked on the plurality of first transistors; and
a second interconnect wiring level on a second side of the stacked structure opposite the first side;
wherein wires of the first interconnect wiring level are spaced apart from each other at a first pitch, and wires of the second interconnect wiring level are spaced apart from each other a second pitch greater than the first pitch.

6. The semiconductor device of claim 5, wherein the first side of the stacked structure is on a frontside of the semiconductor device, and the second side of the stacked structure is on a backside of the semiconductor device.

7. The semiconductor device of claim 5, further comprising at least one contact disposed from the first side of the stacked structure to the second side of the stacked structure, wherein the at least one contact connects a wire of the first interconnect wiring level with a wire of the second interconnect wiring level.

8. The semiconductor device of claim 5, wherein a source/drain region of at least one of the first transistors is connected to a wire of the second interconnect wiring level, and the wire of the second interconnect wiring level is misaligned with the source/drain region.

9. The semiconductor device of claim 8, wherein the source/drain region is connected to the wire through a contact having a first portion overlapping the source/drain region and a second portion overlapping the wire.

10. The semiconductor device of claim 1, wherein the plurality of first transistors and the plurality of second transistors comprise a plurality of nanosheet transistors respectively including a plurality of stacked channel regions.

11. The semiconductor device of claim 10, wherein the plurality of gate isolation regions respectively comprise at least one dielectric layer, and respective ones of the plurality of stacked channel regions in one or more of the plurality of second transistors contact the at least one dielectric layer.

12. The semiconductor device of claim 1, wherein the plurality of gate isolation regions respectively comprise at least one dielectric layer disposed between a gate contact of the plurality of gate contacts and a gate structure of a second transistor of the plurality of second transistors.

13. The semiconductor device of claim 1, further comprising a plurality of additional gate isolation regions disposed through respective gate structures of the plurality of first transistors, wherein the plurality of additional gate isolation regions are offset from the plurality of gate isolation regions.

14. A semiconductor device comprising:
a first transistor structure;
a second transistor structure stacked on the first transistor structure; and
a gate contact disposed through a gate structure of the second transistor structure, wherein the gate contact contacts a gate structure of the first transistor structure, and is isolated from the gate structure of the second transistor structure by a dielectric layer disposed on sides of the gate contact;
wherein the dielectric layer is located at a cell boundary of the second transistor structure.

15. The semiconductor device of claim 14, wherein the gate contact contacts the gate structure of the first transistor structure at a region between n-type and p-type transistors.

16. The semiconductor device of claim 14, further comprising:
a first interconnect wiring level disposed over the second transistor structure; and
a second interconnect wiring level disposed under the first transistor structure;
wherein wires of the first interconnect wiring level are spaced apart from each other at a first pitch, and wires of the second interconnect wiring level are spaced apart from each other a second pitch greater than the first pitch.

17. The semiconductor device of claim 16, wherein:
the first interconnect wiring level is on a frontside of the semiconductor device, and the second interconnect wiring level is on a backside of the semiconductor device; and
the semiconductor device further comprises at least one contact disposed from the frontside of the semiconductor device to the backside of the semiconductor device, wherein the at least one contact connects a wire of the first interconnect wiring level with a wire of the second interconnect wiring level.

18. A semiconductor device comprising:
a first device layer;
a second device layer stacked on the first device layer;
a plurality of gate isolation regions disposed through respective gate structures of the second device layer, wherein the plurality of gate isolation regions overlap respective areas between adjacent transistors in the first device layer; and
a plurality of gate contacts disposed through the plurality of gate isolation regions, wherein the plurality of gate contacts contact gate structures in the respective areas between the adjacent transistors in the first device layer.

19. The semiconductor device of claim 18, wherein the plurality of gate isolation regions respectively comprise at least one dielectric layer disposed between a gate contact of the plurality of gate contacts and a gate structure of the second device layer.

20. The semiconductor device of claim 18, further comprising a plurality of additional gate isolation regions disposed through respective gate structures of the first device layer, wherein the plurality of additional gate isolation regions are offset from the plurality of gate isolation regions.
